(19) United States
(12) Patent Application Publication
(10) Pub. No.: US 2023/0306164 A1
(43) Pub. Date: Sep. 28, 2023

(54) METHOD FOR PREDICTING SAND PRODUCTION IN A FORMATION

(71) Applicant: SAUDI ARABIAN OIL COMPANY, Dhahran (SA)

(72) Inventors: Ammar AlQatari, Dhahran (SA); Murtadha J. AITammar, Dhahran (SA)

(73) Assignee: SAUDI ARABIAN OIL COMPANY, Dhahran (SA)

(21) Appl. No.: 17/655,906

(22) Filed: Mar. 22, 2022

(51) Int. Cl. G06F 30/27; G01V 99/00

(52) U.S. Cl. CPC G06F 30/27; G01V 99/005

(57) ABSTRACT

A method for predicting sand production in a formation, including the steps: drilling a well that penetrates the formation, gathering petrophysical formation evaluation (FE) data and Mechanical Earth Model (MEM) data from the well; entering the FE and MEM data as input into a trained model; determining a critical drawdown pressure (CDP) from the output of the trained model; and predicting the sand production from the CDP.

### BACKGROUND

Wellbores are drilled into a reservoir of a formation to access the fluids stored in the reservoir. The wellbores fill with fluids during the drilling. The pressure that drives the fluids from the reservoir into the wellbore is the pressure drawdown. The tendency of the reservoir to produce sand, limits the pressure drawdown. Sandstone formations are directly impacted due to the nature of sand particles accompanying hydrocarbon during the operation of a well.

Sand production is the migration of sand in a formation caused by the flow of fluids in a reservoir of the formation.

Minimizing the sand production is a challenge due to the large operational costs and time. Predicting sand production is a challenge in the oil and gas industry with direct impact on production of hydrocarbons along with erosion of surface and subsurface facilities. The damage turns feasible into unfeasible projects because of lack of proper preparation and prediction of a time at which the sand particles start to mobilize from the formation.

Accordingly, there exists a need for a method for predicting sand production in a formation.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method for predicting sand production in a formation, comprising the steps: drilling a well that penetrates the formation, gathering petrophysical formation evaluation (FE) data and Mechanical Earth Model (MEM) data from the well; entering the FE and MEM data as input into a trained model; determining a critical drawdown pressure (CDP) from the output of the trained model; and predicting the sand production from the CDP.

Other aspects and advantages of the claimed subject matter will be apparent from the following description and the appended claims.

### BRIEF DESCRIPTION OF DRAWINGS

The following figures are included to illustrate certain aspects of the embodiments and should not be viewed as exclusive embodiments. The subject matter disclosed is amenable to considerable modifications, alterations, combinations, and equivalents in form and function, as will occur to those skilled in the art and having the benefit of this disclosure.

FIG. 1 shows a drilling system, according to one or more embodiments.

FIG. 2 shows the trained model and the inputs and the output of the trained model, according to one or more embodiments.

FIG. 3 shows a flowchart of the method steps for predicting sand production in a formation, according to one or more embodiments.

FIG. 4 shows another flowchart of the method steps for predicting sand production in a formation, according to one or more embodiments.

FIG. 5A shows a methodology of feeding filtered data to be trained for prediction purposes, according to one or more embodiments

FIG. 5B shows main and associated inputs which are weighted along the depth of the well, according to one or more embodiments.

FIG. 5C shows a plot of the predicted CDP vs. measured CDP, according to one or more embodiments.

FIG. 5D shows overlaying synthetic and acquired data for validation purposes, according to one or more embodiments.

FIG. 5E shows a quantified clay volumes are populated using a calculated probabilistic petrophysical model to be used as productivity indicator, according to one or more embodiments.

FIG. 6 illustrates a computer system according to one or more embodiments.

### DETAILED DESCRIPTION

In the following discussion, numerous specific details are set forth to provide a thorough understanding of the present disclosure. However, it will be obvious to those skilled in the art that embodiments of the present disclosure can be practiced without such specific details. Additionally, for the most part, details concerning well drilling, reservoir testing, well completion and the like have been omitted inasmuch as such details are not considered necessary to obtain a complete understanding of the present disclosure, and are considered to be within the level of skill of persons having ordinary skill in the relevant art.

In one aspect, embodiments disclosed herein relate to a method for predicting sand production in a formation, comprising the steps: gathering petrophysical formation evaluation (FE) data and Mechanical Earth Model (MEM) data, entering the FE and MEM data in a trained model that outputs a critical drawdown pressure (CDP), which indicates the sand production in the formation. The properties of FE and MEM is depicted in plots showing data points (x-axis) versus depth (y-axis).

Embodiments of the present disclosure may provide at least one of the following advantages.

The CDP is vital for the estimation of sand production and is analytically calculated using raw FE data along with calculated 1-D MEM data. The prediction of a time at which the sand particles start to mobilize does not need all the inputs for the analytical calculation of CDP and is calculated only with FE and MEM data.

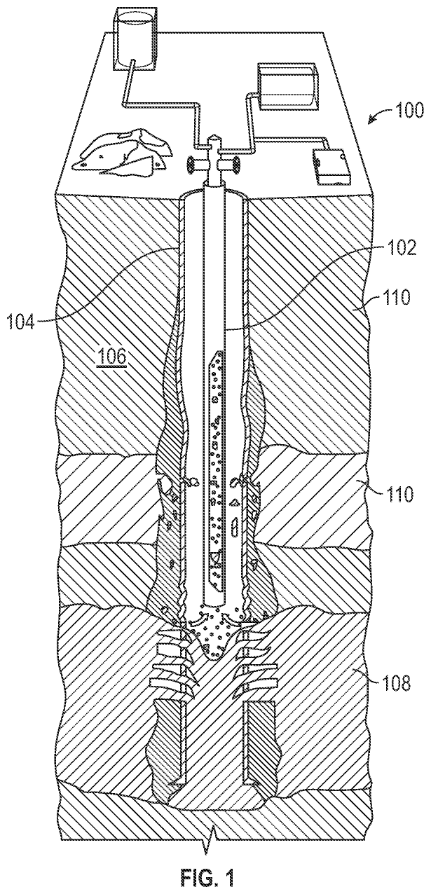

FIG. 1 shows a drilling system 100 comprising a drill string 102 that drills a wellbore 104 into a formation 106. While the drill string 102 is drilling the wellbore 104, sand 108 and other debris 110 may enter the wellbore 104. The mobility of sand particles during the sand production influences the efficiency of extracting oil and gas from the wellbore. Sand production is undesirable because sand production restricts productivity, erode completion components, impede wellbore access, interfere with the operation of downhole equipment, and present significant disposal difficulties.

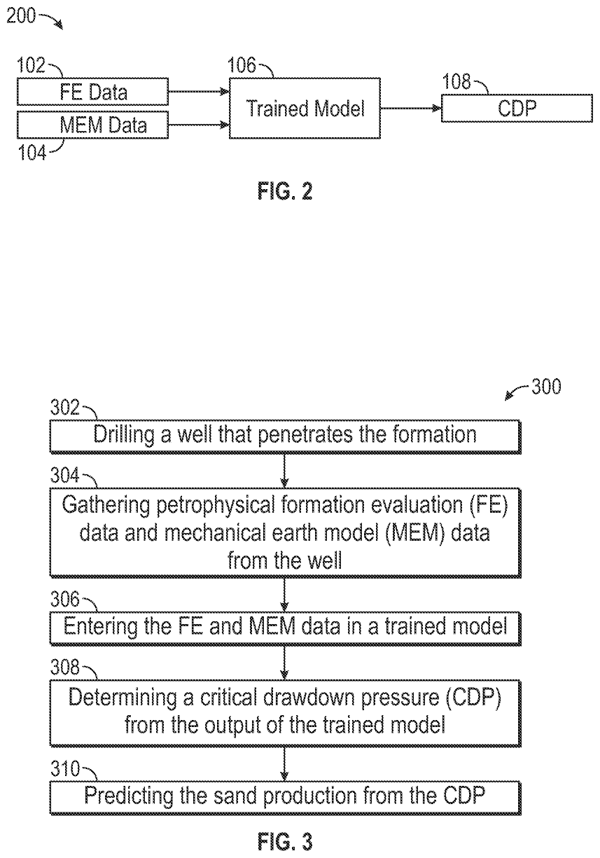

To predict the sand production, the method for predicting sand production in a formation comprises the steps of entering the FE and MEM data into a trained model and determining the CDP from the output of the trained model. These steps are described in the following FIG. 2.

FIG. 2 shows the trained model 106 and the inputs and the output of the trained model 106. FE and MEM data 102, 104 are entered into the trained model which comprises a set of data inputs and outputs that are clustered, and that are statistically ranked against the offset data 106. The trained model 106 comprises any machine learning algorithm such as Extra Trees algorithm, XGBoost algorithm, Neural Networks (NN), Deep Neural Networks (DNN), Convolutional Neural Networks (CNN), or any other algorithm.

The FE data 102 are the measurement and analysis of the formation and its fluid properties and determines the quantity and producibility of fluids in the reservoir. The FE data determines the commercial ability of a borehole to produce petroleum. In one or more embodiments, the FE data comprise porosity, permeability, and water saturation that permit profitable production from the formation.

The MEM data 104 represent the mechanical properties of rocks, stresses, pressures, and temperatures acting on the rocks at a certain depth. Each data point in the MEM is referenced to its 3D spatial coordinates and time of sample collection. The MEM data comprises stress, fluid pressure, temperature, fluid content, pore pressure and magnitude and orientation of the maximum, intermediate and minimum principal stresses.

The CDP 108 is the maximum difference between a reservoir pressure PF and a minimum well bottom hole flowing pressure Pw that the formation withstands without sand being produced along with the formation fluid. A negative CPD indicates that the formation will produce sand during the production of formation fluids. The CDP is calculated by P_{CD}=P_{F}−P_{W,Min}. The CDP is the pressure that mobilizes sand particles in a certain environment and is calculated analytically, as shown in FIG. 3. The CDP is used to predict sand production.

FIG. 3 shows a flowchart 300 of the method steps for predicting sand production in a formation. The method comprises the following steps.

In step 302, a well is drilled that penetrates the formation.

In step 304, FE data and MEM data are gathered from acquired raw logs captured at the field and measured MEM data from core measurements from the well. In step 306, the FE and MEM data are input into a trained model. For example, the trained model may be that shown in FIG. 2.

In step 308, a critical drawdown pressure (CDP) is determined from the output of the trained model. The CDP indicates the sand production in the formation. The CDP is the measure of when the sand particles will mobilize from the formation and therefore a direct indicator of sand production.

In step 310, the sand production is determined from the CDP.

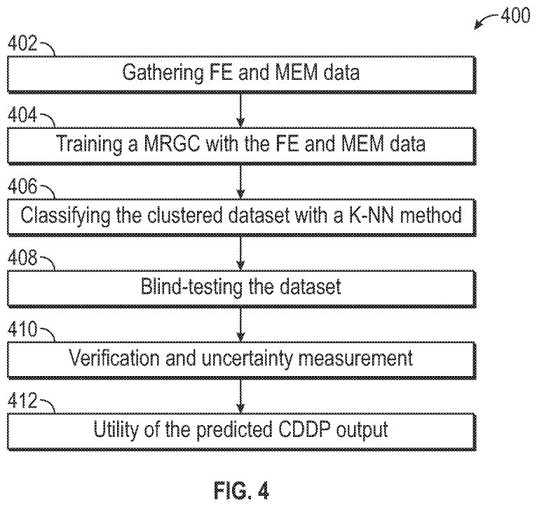

FIG. 4 shows a flowchart of the method steps for predicting sand production in a formation.

In step 402, raw FE data and MEM data are gathered. The FE and MEM data are comprised in a dataset or data log.

In step 404, a multi-resolution graph-based clustering (MRGC) is trained with the FE and MEM data. The MRGC uses the ranking of the FE and MEM data which is a statistical analysis that compares the offset data against the impact of change per data point and rank inputs per the impact value associated. The MRGC outputs the number of the clusters and uses the FE and MEM data to propagate the outputted number of the clusters. The number of the clusters is outputted during the training of the trained model and not during the entering of the FE and MEM data. The assessment of how many clusters is done using a trial and error method by going back and forth and assessing the error margin with different number of clusters to determine which fit best.

The training of step 204 is performed using a machine learning (ML) algorithm. In one or more embodiments, multi-resolution graph-based clustering (MRGC) is utilized to predict critical drawdown pressure (CDP) across a depth interval of the well. The CDP utilizes 1-D MEM and acquired raw FE data as inputs. In other embodiments, the machine learning algorithm is any suitable machine learning algorithm such as Extra Trees algorithm, XGBoost algorithm, Neural Networks (NN), Deep Neural Networks (DNN), Convolutional Neural Networks (CNN), etc.

Core data and an auditing tool are used to audit for accuracy of the inputted FE and MEM data. The core data is an object graph and persistence framework. The object graph is a view of an object system at a time. An object system is part of object-oriented programming which is a programming paradigm based on objects. The object contains data in form of fields, and codes in form of procedures. Programming paradigms are a way to classify programming languages based on their features. The core data is not used in the training process.

In one or more embodiments, the inputs for the training are pore pressure, minimum horizontal stress, inclination of the wellbore (dip), and unconfined compressive strength (UCS).

The pore pressure is the hydrostatic pressure of fluids within the pores of a reservoir exerted by a column of water from the formation's depth to sea level. The UCS measures a strength of the rocks in a formation. The UCS is the maximum axial compressive stress that a right-cylindrical rock sample withstands under unconfined conditions.

The minimum horizontal stress is a direct result of overburden stress. Poisson's ratio determines the amount of stress transmitted horizontally. The minimum horizontal stress is obtained by using equation:

$${σ}_{h , min} = \frac{v}{1 - v} \times ( {σ}_{v} - α {P}_{P} ) + α {P}_{P} + {P}_{Tectonic} ,$$

where v is the Poisson's ratio, a,, is the vertical stress in psi, α is the Biot's constant, and P_{P} is the pore pressure in psi, P_{Tectonic} is the tectonic pressure in psi.

In step 406, a k-NN is trained with the clustered training dataset which is the statistically ranked data from the MRGC step clustered by similarities in patterns per data point. The k-NN allows for setting the number k of the k-NN, which is the normalized distance between the data point to be predicted and its nearest neighbors. The k-NN depends on both the data points and the MRGC.

The ML algorithm is based on graph clustering coupled with k-NN algorithm to output the critical drawdown pressure (CDP). The k-NN algorithm is performed right after or back-to-back with the MRGC algorithm, which defines the coupling of the k-NN and the MRGC.

The inputs of the ML model comprise pore pressure, minimum and maximum horizontal stress, inclination and azimuth, and unconfined compressive strength, Poisson's ratio, and vertical horizontal stress. The ML model links the inputs to the output. In case one of the inputs is missing (i.e., there is a missing link) then the missing link is predicted. In other words, the missing link occurs when one of the key ingredients are not present that jeopardizes the analytical calculation of the time the formation starts to sand. Therefore, machine learning (ML) using multi-resolution graph-based clustering (MRGC) coupled with K-nearest neighbors (k-NN) is used to bridge the gap and produce the missing data to establish the estimation needed to predict sanding. In other embodiments, the ML algorithm could be any ML algorithm such as Extra Trees algorithm, XGBoost algorithm, Neural Networks (NN), Deep Neural Networks (DNN), Convolutional Neural Networks (CNN), or any other algorithm.

The offset data comprises log patterns which are similarities in the offset data. The log patterns are created by ranking of similar data against depth and show a pattern which the system recognizes and clusters. A ranking of different log patterns are created. The number k of the k-NN is the normalized distance between the point to be predicted and its nearest neighbors. As an example, the MRGC uses a selection of common log patterns and off-set patterns which are plots with data against depth that show a similar theme. Offset patterns are obtained through ranking of what is similar (data vs depth). In one or more embodiments, the number k is equal to 12.

The wells are analyzed collectively as all the FE and MEM data are gathered from the tested wells and apply a pattern recognition to rank data points of the log patterns. The wells are tested against real captured data from the field. Basically, trained data vs real data are put against each other, and then the error margin is calculated. Depth is a data point of the log patterns that is marked when a log pattern is expected or not expected.

The FE and MEM data inputted to the model for training purposes and are weighted from top to bottom of the well. The first input has the largest impact and all other inputs are weighted equally. The log patterns are recognized from a MRGC of data points of the log patterns.

The MRGC of data and assessing the number of clustering is done in step 406. Then the number k of the k-NN is chosen for the k-NN method and a distance between the data points is set. Both MRGC and k-NN are coupled for training purposes.

The training comprises a MRGC method coupled with k-NN to predict intervals along the depth of the well, which are prone to sanding. Therefore, it is used as an indicator of sand severity within the borehole.

In step 408, the clustered training dataset is blind-tested. The blind testing is done against analytically calculated CDP from calculated 1-D geomechanical data. The blind-testing is done against real captured data from the field. Thus, actual vs. trained data are compared to calculate the margin of error. The testing algorithm is done using MRGC and k-NN then ranking the results statistically as mentioned previously.

Geomechanical data comprise in-situ rock stress, modulus of elasticity, leak-off coefficient, and Poisson's ratio. Techniques for obtaining geomechanical data for geomechanical models are: coring and core testing, geophysical log analysis, well testing methods such as transient pressure analysis, hydraulic fracturing stress testing, and geophysical methods such as acoustic emission.

An error margin is set (not exceeding 20 percent of error) per depth. Training and blind testing with FE and MEM data only is an advantage because not all conventional inputs are needed to calculate the CDP.

Steps 406 and 408 go hand in hand as training steps to capture all data needed and generate synthetic data based on inputted FE and MEM data.

In step 410, verification and uncertainty measurements are performed. Verification represents an error margin calculated between a real and predicted data set. Uncertainty represents how much of an error is present in the predicted data which leads to uncertain results. In this step, the input dataset is verified as not having missing data and that it covers the intended interval.

In step 412, the predicted CDP is outputted. The predicted synthetic data of CDP is used in wells where an analytical method cannot be calculated due to missing data.

All steps 402-412 are crucial to be followed strictly to capture sanding severity along the depth versus the pressure required for the first sand particle to flow.

The method for predicting sand production generates synthetic CDP data even if physical inputs are missing and uses a ML algorithm to output synthetic CDP data with low uncertainty. The outputted synthetic CDP data are generated by a computer simulation that approximates the real CDP data. However, the synthetic CDP data is algorithmically generated by the computer simulation.

The prediction of the CDP shows a good match with CDP values, as shown in FIGS. 3A-3E.

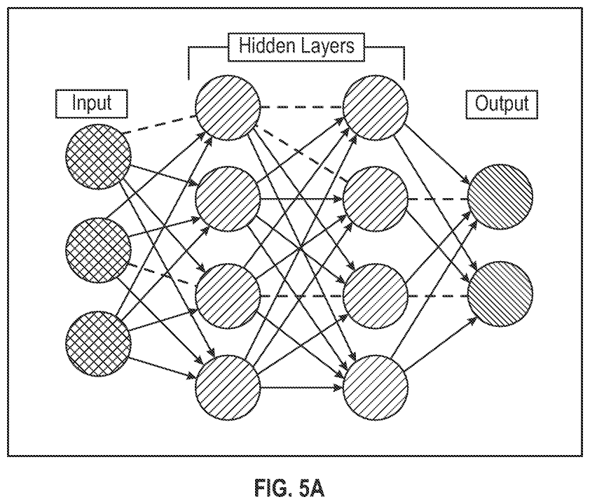

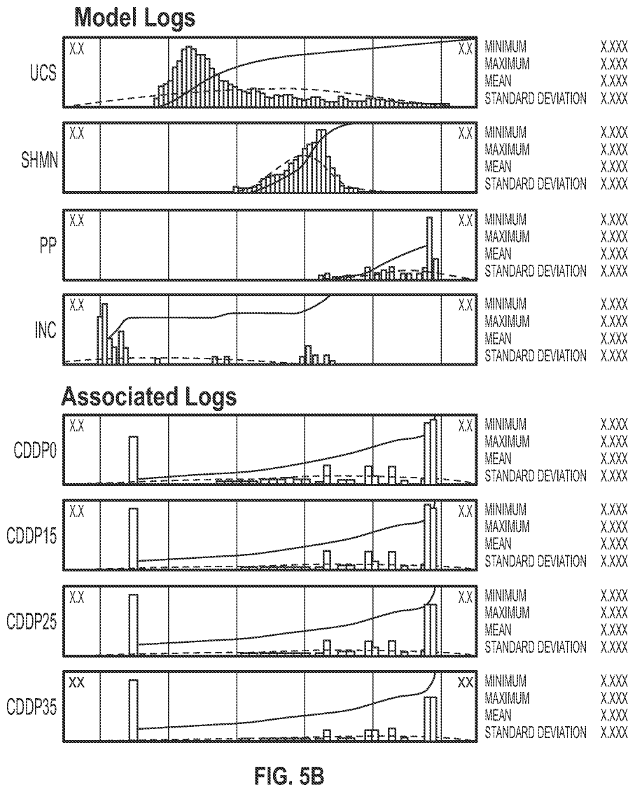

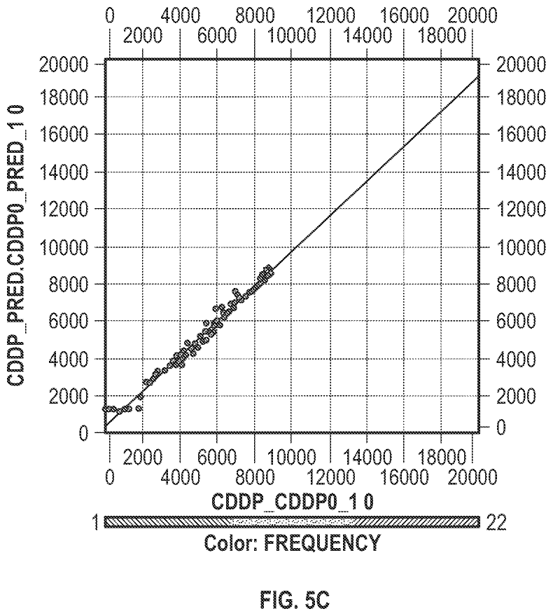

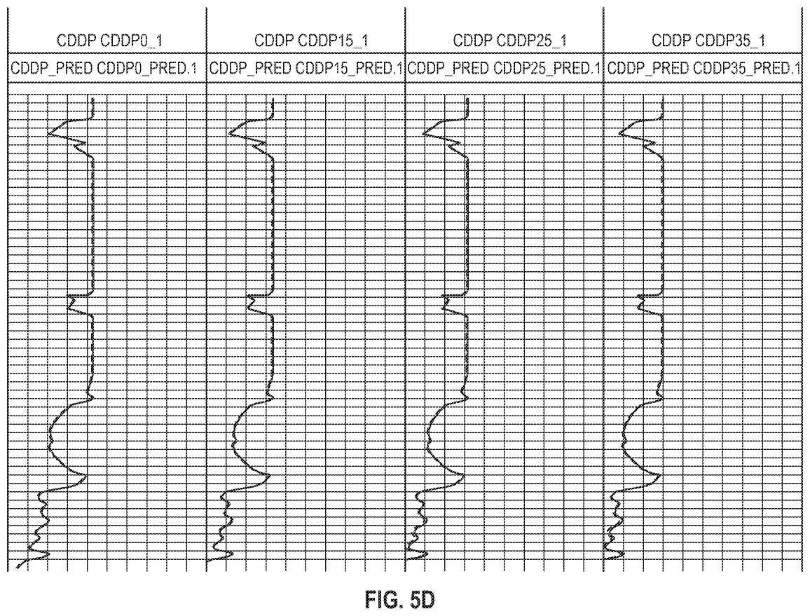

FIG. 5A shows a methodology of feeding filtered data to be trained for prediction purposes. The data are filtered to capture missing data points, so that a complete dataset is obtained before feeding the dataset into the ML model. Specifically, the hidden layers of FIG. 5A represent a machine learning algorithm such as a neural network, where a hidden layer includes one or more neurons. A neuron may be a modelling node or object that is loosely patterned on a neuron of the human brain. In particular, a neuron may combine data inputs with a set of coefficients, i.e., a set of network weights for adjusting the data inputs. These network weights may amplify or reduce the value of a particular data input, thereby assigning an amount of significance to various data inputs for a task being modeled. Through machine learning, a neural network may determine which data inputs should receive greater priority in determining one or more specified outputs of the neural network. Likewise, these weighted data inputs may be summed such that this sum is communicated through a neuron's activation function to other hidden layers within the neural network. As such, the activation function may determine whether and to what extent an output of a neuron progresses to other neurons where the output may be weighted again for use as an input to the next hidden layer.

FIG. 5B shows main logs (model logs) and associated inputs (associated logs) which are weighted along the depth of the well.

The model logs include UCS, minimum horizontal stress (SHMN), pore pressure (PP) and inclination of the wellbore (INC). The model logs are inputs that are always included in both the trained datasets and the blind-tested datasets.

The associated logs are inputs that need to be predicted. Therefore, the ML model tries to learn the patterns of the associated inputs and compare them with the main inputs. In particular, the associated logs are learned and predicted by capitalizing the log patterns on the main inputs of a trained dataset. The associated logs are the CDP indicating the pressure it takes for a sand particle to mobilize. The numbers of the CDP (0, 15, 25, 35) indicate the depletion rate of the reservoir giving a time dependency on the predicted dataset. The minima and maxima indicate the x-axis which are the frequency of each model element.

FIG. 5C shows a plot of the predicted CDP vs. measured CDP. The plot shows that predicted CDP and the measured CDP match within an error margin, such that the quality of the model is validated. The x-axis shows the original data and the y-axis shows the predicted data. FIG. 5C shows the error margin in terms of original vs predicted data. As can be seen from the plot, the predicted CDP and the measured CDP match within an error margin, such that the quality of the model is validated.

FIG. 5D shows an overlaying of synthetic and acquired data for validation purposes. The synthetic and acquired data are laid on top of each other for viewing purposes. Then, the error margin between both data sets is calculated. FIGS. 5A to 5E are overlayed predicted vs real data for comparison purposes.

FIG. 5E shows a quantified clay volumes that are populated using a calculated probabilistic petrophysical model to be used as productivity indicator. The quantified clay volumes is directly related to production of hydrocarbon. The x-axis denotes the frequency and the y-axis denotes the data input values.

The first column to the left indicates the lithology types including sand 502, illite clay 504, and orthoclase clay 506. The next two column show a comparison of original (second column from the left) and predicted data (third column from the left). Each line in each column shows CDP0 to CDP35 from left to right. The numbers 0, 15, 25, 35 next to CDP indicate depletion percentage of the reservoir.

The probabilistic petrophysical model is a model with no specific equation to calculate the output. Thus, the probabilistic petrophysical model uses a max and min to give the analyzer the choice to choose the fit of a petrophysical model. A petrophysical model is a model at which an analyzer is using raw captured data from the field to calculate multiple outputs. For this subject the analyzer is calculating clay content in volumes.

The method utilizes UCS from physical core data of nearby wells, minimum horizontal stress which is calculated from 1-D geomechanical models based on log and core data, pore pressure based on physical formation testing which is done during the drilling phase, and well inclination trajectory to capture the sensitivity of angle to sand production.

The additional associated inputs are calculated based on total 1-D geomechanical model which utilizes the analytically calculating CDP under several depletion rates of the pressure in the formation measured in percentage.

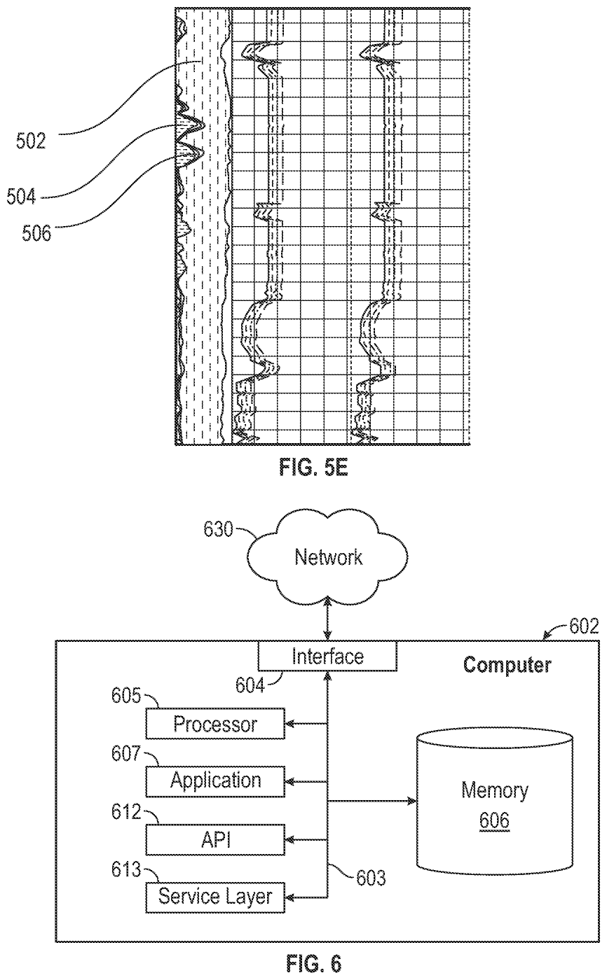

FIG. 6 is a block diagram of a computer system 602 used to provide computational functionalities associated with the method for predicting sand production in a formation.

The illustrated computer system 602 is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer system 602 comprises a computer that comprises an input device, such as a keypad, keyboard, touch screen, or other device that can accept user information, and an output device that conveys information associated with the operation of the computer system 602, including digital data, visual, or audio information (or a combination of information), or a GUI.

The computer system 602 serves in a role as a client, network component, a server, a database or other persistency, or any other component (or a combination of roles) of a computer system for performing the subject matter described in the instant disclosure. The illustrated computer system 602 is communicably coupled with a network 630 or cloud. In some implementations, one or more components of the computer system 602 are configured to operate within environments, including cloud-computing-based, local, global, or other environment (or a combination of environments).

At a high level, the computer system 602 is an electronic computing device operable to receive, transmit, process, store, or manage data and information associated with the described subject matter. According to some implementations, the computer system 602 also comprises or is communicably coupled with an application server, e-mail server, web server, caching server, streaming data server, business intelligence (BI) server, or other server (or a combination of servers).

The computer system 602 receives the FE and MEM data over a network 630 or cloud from a client application (for example, executing on another computer system 602 and responding to the received requests by processing the said requests in an appropriate software application. In addition, requests may also be sent to the computer system 602 from internal users (for example, from a command console or by other appropriate access method), external or third-parties, other automated applications, as well as any other appropriate entities, individuals, systems, or computers.

Each of the components of the computer system 602 communicates using a system bus 603. In some implementations, any or all of the components of the computer system 602, both hardware or software (or a combination of hardware and software), may interface with each other or the interface 604 (or a combination of both) over the system bus 603 using an application programming interface (API) 612 or a service layer 613 (or a combination of the API 612 and service layer 613. The API 612 comprises specifications for routines, data structures, and object classes. The API 612 is either computer-language independent or dependent and refer to a complete interface, a single function, or even a set of APIs. The service layer 613 provides software services to the computer system 602 or other components (whether or not illustrated) that are communicably coupled to the computer system 602. The functionality of the computer system 602 is accessible for all service consumers using this service layer. Software services, such as those provided by the service layer 613, provide reusable, defined business functionalities through a defined interface. For example, the interface is software written in JAVA, C++, or other suitable language providing data in extensible markup language (XML) format or other suitable format. While illustrated as an integrated component of the computer system 602, alternative implementations may illustrate the API 612 or the service layer 613 as stand-alone components in relation to other components of the computer system 602 or other components (whether or not illustrated) that are communicably coupled to the computer system 602. Moreover, any or all parts of the API 612 or the service layer 613 are implemented as child or sub-modules of another software module, enterprise application, or hardware module without departing from the scope of this disclosure.

The computer system 602 comprises an interface 604. Although illustrated as a single interface 604 in FIG. 6, two or more interfaces 604 are used according to particular needs, desires, or particular implementations of the computer system 602. The interface 604 is used by the computer system 602 for communicating with other systems in a distributed environment that are connected to the network 630. Generally, the interface 604 comprises logic encoded in software or hardware (or a combination of software and hardware) and operable to communicate with the network 630 or cloud. More specifically, the interface 604 comprises software supporting one or more communication protocols associated with communications such that the network 630 or interface's hardware is operable to communicate physical signals within and outside of the illustrated computer system 602.

The computer system 602 comprises at least one computer processor 605. Although illustrated as a single computer processor 605 in FIG. 6, two or more processors are used according to particular needs, desires, or particular implementations of the computer system 602. Generally, the computer processor 605 executes instructions according to the trained model and manipulates the FE and MEM data to perform the operations of the computer system 602 and any algorithms, methods, functions, processes, flows, and procedures as described in the instant disclosure to output the CDP, that indicates the sand production in the formation.

The computer system 602 also comprises a memory 606 that holds the FE and

MEM data for the computer system 602 or other components (or a combination of both) that is connected to the network 630. For example, the memory 606 is a database storing the FE and MEM data consistent with this disclosure. Although illustrated as a single memory 606 in FIG. 6, two or more memories are used according to particular needs, desires, or particular implementations of the computer system 602 and the described functionality. While memory 606 is illustrated as an integral component of the computer system 602, in alternative implementations, memory 606 is external to the computer system 602.

The application 607 is an algorithmic software engine providing functionality according to particular needs, desires, or particular implementations of the computer system 602, particularly with respect to functionality described in this disclosure. For example, application 607 serves as one or more components, modules, applications, etc. Further, although illustrated as a single application 607, the application 607 is implemented as multiple applications 607 on the computer system 602. In addition, although illustrated as integral to the computer system 602, in alternative implementations, the application 607 is external to the computer system 602.

There are any number of computers 602 associated with, or external to, a computer system containing computer system 602, each computer system 602 communicating over network 630. Further, the term “client,” “user,” and other appropriate terminology are used interchangeably as appropriate without departing from the scope of this disclosure. Moreover, this disclosure contemplates that many users may use one computer system 602, or that one user may use multiple computers 602.

In some embodiments, the computer system 602 is implemented as part of a cloud computing system. For example, a cloud computing system comprises one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which are performed using one or more Internet connections. More specifically, a cloud computing system may operate according to one or more service models, such as infrastructure as a service (IaaS), platform as a service (PaaS), software as a service (SaaS), mobile “backend” as a service (MBaaS), artificial intelligence as a service (AIaaS), serverless computing, and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed:

1. A method for predicting sand production in a formation, comprising the steps:
drilling a well that penetrates the formation,
gathering petrophysical formation evaluation (FE) data and Mechanical Earth Model (MEM) data from the well;
entering the FE and MEM data as input into a trained model;
determining a critical drawdown pressure (CDP) from the output of the trained model; and
predicting the sand production from the CDP.

2. The method according to claim 1, wherein the FE and MEM data are gathered as plots showing data points versus depth of the well.

3. The method according to claim 1, wherein the trained model comprises multi-resolution graph-based clustering (MRGC).

4. The method according to claim 1, wherein the trained model comprises a k-nearest neighbors (k-NN) algorithm.

5. The method according to claim 1, wherein the trained model comprises MRGC and k-NN, wherein the MRGC algorithm is performed after the k-NN algorithm.

6. The method according to claim 1, wherein the trained model is trained by classifying a training dataset with k-NN, and blind-testing the classified dataset with the training dataset and the testing dataset.

7. The method according to claim 1, wherein the FE data comprises porosity, permeability, and water saturation of the formation.

8. The method according to claim 1, wherein the MEM data comprises stress, fluid pressure, temperature, fluid content, pore pressure and magnitude and orientation of the maximum, intermediate and minimum principal and horizontal stresses, inclination of the wellbore (dip), and unconfined compressive strength.

9. The method according to claim 1, wherein a number of clusters is assessed as a result of the training of the trained model.

10. The method according to claim 9, wherein the number of clusters is assessed using a trial and error method by going back and forth and assessing an error margin with different number of clusters to determine which fit best.

11. The method according to claim 1, wherein at least one of the FE and MEM data are weighted with weighting factors.

12. The method according to claim 9, wherein the weighting factors decrease as function of the depth of a well.

13. The method according to claim 1, wherein the model calculates the CDP by the maximum difference between a reservoir pressure and a minimum well bottom hole flowing pressure Pw that the formation withstands without sand being produced along with the formation fluid: P_{CD}=P_{F}=P_{W,Min}.

14. The method according to claim 1, wherein the trained model comprises any machine learning algorithm such as Extra Trees algorithm, XGBoost algorithm, Neural Networks (NN), Deep Neural Networks (DNN), Convolutional Neural Networks (CNN), or any other algorithm.

15. The method according to claim 1, wherein the FE and MEM data are ranked in a statistical analysis that compares offset data against the impact of change per data point and rank inputs per impact.

16. The method according to claim 15, wherein the MRGC uses the ranking of the FE and MEM data.
